(19) United States
(12) Patent Application Publication
(10) Pub. No.: US 2010/0187690 A1
(43) Pub. Date: Jul. 29, 2010

(54) SEMICONDUCTOR DEVICE

(75) Inventors: Kiyokazu OKADA, Yokkaichi-shi (JP); Taku NISHIYAMA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/696,513

(22) Filed: Jan. 29, 2010

(30) Foreign Application Priority Data
Jan. 29, 2009 (JP) 2009-018534

(51) Int. Cl. H01L 23/488; H01L 25/065

(52) U.S. Cl. 257/738; 257/777; 257/E25.013; 257/E23.023

(57) ABSTRACT

A semiconductor device includes a wiring substrate having connection pads. A first semiconductor chip is mounted on the wiring substrate. A second semiconductor chip is stacked on the first semiconductor chip in a step-like shape. Electrode pads of the first semiconductor chip are electrically connected to the connection pads of the wiring substrate via first metal wires. Electrode pads of the second semiconductor chip are electrically connected to the electrode pads of the first semiconductor chip via second metal wires. One end of the second metal wire is connected from above metal bump formed on the first electrode pad.

### CROSS REFERENCE TO RELATED APPLICATIONS

This application is based upon and claims the benefit of priority from the prior Japanese Patent Application No. 2009-018534, filed on Jan. 29, 2009; the entire contents of which are incorporated herein by reference.

### BACKGROUND OF THE INVENTION

A memory card (semiconductor memory card) housing a NAND-type flash memory or the like is in a rapid trend of getting smaller and having a higher capacity. In order to realize a miniaturized memory card, semiconductor chips such as memory chips, controller chips or the like are mounted by being stacked on a wiring substrate. Further, in order to realize a higher capacity in a memory card, memory chips themselves also tend to be stacked in multiple layers on a wiring substrate. Electrode pads of the memory chip and the controller chip are electrically connected to connection pads of the wiring substrate by applying wire bonding.

When semiconductor chips such as memory chips are stacked in multiple layers, a structure in which a plurality of semiconductor chips are stacked in a step-like shape to expose respective electrode pads is adopted (see JP-A2007-019415 (KOKAI), JP-A 2008-085032 (KOKAI)). When wire bonding is performed on the semiconductor chips stacked in the step-like shape, in order not to disturb wire bonding to the electrode pad of the lower semiconductor chip, it is necessary to dispose the upper semiconductor chip to be offset from an edge of the lower semiconductor chip by about 400 μm. This is based on a shape of a capillary for wire bonding.

If an offset of the upper semiconductor chip is insufficient, there is a possibility that a capillary of a bonding equipment contacts an edge of an upper semiconductor chip at a time of wire bonding to an electrode pad of a lower semiconductor chip. Thus, when wire bonding is performed to semiconductor chips stacked in a step-like shape, the upper semiconductor chip is offset from an edge of the lower semiconductor chip by about 400 μm. Since such an offset causes hampering miniaturization of a device size, a connection structure of a metal wire enabling reduction of an offset of an upper semiconductor chip is required.

### BRIEF SUMMARY OF THE INVENTION

A semiconductor device according to a first aspect of the present invention includes: a wiring substrate having connection pad; a first semiconductor chip, mounted on the wiring substrate, having first electrode pads arranged along at least one outer edge and metal bumps formed on the first electrode pads; a second semiconductor chip, stacked on the first semiconductor chip and displaced in a direction orthogonal to an arranging direction of the first electrode pad to expose the first electrode pads, having second electrode pads arranged along at least one outer edge; first metal wires electrically connecting the connection pads of the wiring substrate and the first electrode pads of the first semiconductor chip; second metal wires electrically connecting the first electrode pads of the first semiconductor chip and the second electrode pads of the second semiconductor chip; and a sealing resin layer formed on the wiring substrate to seal the first and second semiconductor chips together with the first and second metal wires, wherein one ends of the second metal wires are connected from above the metal bumps.

A semiconductor device according to a second aspect of the present invention includes: a wiring substrate having connection pads; a first semiconductor chip, mounted on the wiring substrate, having first electrode pads arranged along at least one outer edge; a second semiconductor chip, stacked on the first semiconductor chip and displaced in an arranging direction of the first electrode pads and in a direction orthogonal to the arranging direction to expose the first electrode pad, having second electrode pads arranged along at least one outer edge; first metal wires electrically connecting the connection pads of the wiring substrate and the first electrode pads of the first semiconductor chip; second metal wires electrically connecting the first electrode pads of the first semiconductor chip and the second electrode pads of the second semiconductor chip, the second metal wires being wired in an oblique direction in relation to the direction orthogonal to the arranging direction of the first electrode pads; and a sealing resin layer formed on the wiring substrate to seal the first and second semiconductor chips together with the first and second metal wires.

### BRIEF DESCRIPTION OF THE DRAWINGS

FIG. 1 is a plan view showing a semiconductor device according to a first embodiment.

FIG. 2 is a cross-sectional view showing a connection state between first and second semiconductor chips and a wiring substrate by a metal wire in the semiconductor device shown in FIG. 1.

FIG. 3 is a cross-sectional view showing an example of a connection state of a second metal wire to an electrode pad of a first semiconductor chip in the semiconductor device shown in FIG. 1.

FIG. 4 is a cross-sectional view showing another example of a connection state of a second metal wire to an electrode pad of a first semiconductor chip in the semiconductor device shown in FIG. 1.

FIG. 5 is a plan view showing a connection state between first and second semiconductor chips and a wiring substrate by a metal wire in a semiconductor device shown in FIG. 1.

FIG. 6 is a plan view showing a semiconductor device according to a second embodiment.

FIG. 7 is a cross-sectional view showing a connection state between first, second and third semiconductor chips and a wiring substrate by a metal wire in the semiconductor device shown in FIG. 6.

FIG. 8 is a plan view showing an example of a connection state between first, second and third semiconductor chips and a wiring substrate by a metal wire in the semiconductor device shown in FIG. 6.

FIG. 9 is a plan view showing another example of a connection state between first, second and third semiconductor chips and a wiring substrate by a metal wire in the semiconductor device shown in FIG. 6.

### DETAILED DESCRIPTION OF THE INVENTION

Hereinafter, embodiments for practicing the present invention will be described with reference to the drawings.

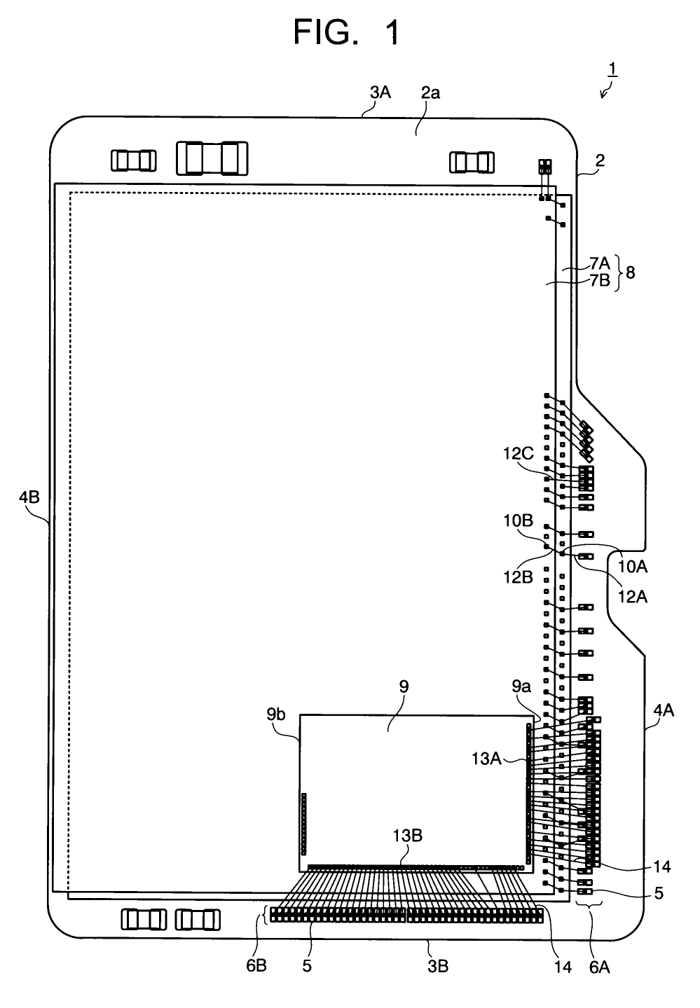

FIG. 1 is a view showing a constitution of a first embodiment in which a semiconductor device of the present invention is applied to a semiconductor memory card. A semiconductor device (semiconductor memory card) 1 shown in FIG. 1 includes a wiring substrate 2 being both a chip mounting substrate and a terminal formation substrate. The wiring substrate 2 is provided with a wiring network inside or on a surface of an insulating resin substrate for example, and more specifically a printed wiring board to which a glass epoxy resin, a BT resin (Bsmaleimide-Triazine resin) or the like is used is applied.

A surface 2a of the wiring substrate 2 is a chip mounting surface. A rear surface (not shown) of the wiring substrate 2 is a terminal formation surface. When a semiconductor memory card is constituted by the semiconductor device 1, an input/output terminal (external connection terminal) of the memory card is formed on the rear surface of the wiring substrate 2. Application of the semiconductor device 1 of this embodiment is not limited to the semiconductor memory card but the semiconductor device 1 can be also applied to a semiconductor package such as a BGA package and an LGA package. In such a case, an external connection terminal (projecting terminal by a solder ball) for the BGA package or an external connection terminal (metal land) for the LGA package is formed on the rear surface of the wiring substrate 2.

The wiring substrate 2 has an outer shape of an approximate rectangle. A first shorter edge 3A of the wiring substrate 2 corresponds to a front end portion at a time that the memory card 1 is inserted into a card slot. A second shorter edge 3B corresponds to a rear portion of the memory card 1. A first longer edge 4A of the wiring substrate 2 has a cutout portion and a narrow portion to indicate front/rear and obverse/reverse of the memory card 1. A second longer edge 4B of the wiring substrate 2 is linear in shape. Each corner of the wiring substrate 2 is curved in shape (R-shaped).

The surface 2a of the wiring substrate 2 has a chip mounting region and pad regions 6 (6A, 6B) on which connection pads 5 being bonding portions at a time of wire bonding are provided. The connection pads 5 constitute a part of a first wiring network (not shown) formed on the surface 2a of the wiring substrate 2, and further are electrically connected to the external connection terminal (not shown) or a second wiring network (not shown) formed on the rear surface side of the wiring substrate 2 via an inner wiring (through hole or the like), which is not illustrated, of the wiring substrate 2. The connection pads 5 are disposed in the first pad region 6A along the first longer edge 4A and in the second pad region 6B along the second shorter edge 3B of the wiring substrate 2 respectively.

On the surface 2a of the wiring substrate 2, there are stacked a plurality of memory chips (semiconductor ships) 7A, 7B. As the memory chips 7A, 7B, NAND-type flash memories are used for example. The plural memory chips 7A, 7B constitute a memory chip group 8. A controller chip (semiconductor chip) 9 is stacked on the memory chip group 8. The controller chip 9 selects the memory chip 7 to write/read data in/from the plural memory chips 7A, 7B and performs writing of data to the selected memory chip 7 or reading of data stored in the selected memory chip 7.

The first and second memory chips 7A, 7B have the same rectangular shapes and include electrode pads 10A, 10B respectively. The first and second electrode pads 10A, 10B are each arranged along ones of outer edges of the first and second memory chips 7A, 7B, more specifically along ones of longer edges thereof. The first and second memory chips 7A, 7B have single-long-side pad structures. The pad structure of the memory chip (semiconductor chip) 7 is not limited to the single-long-side pad structure but the memory chip (semiconductor chip) 7 can be any one having a structure in which an electrode pad is arranged along at least one outer edge such as a single-short-side pad structure and an L-shaped pad structure.

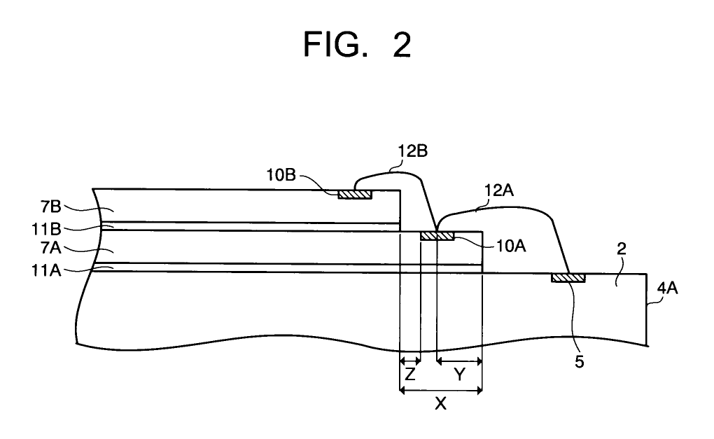

The first memory chip 7A is adhered on the wiring substrate 2 via a first adhesive layer 11A as shown in FIG. 2. A general adhesive film or adhesive paste mainly composed of a polyimide resin, an epoxy resin, an acrylic resin or the like is used for the adhesive layer 11A. The same thing applies to an adhesive layer 11B of the second memory chip 7B. The first memory chip 7A is disposed in a manner that the outer edge along which the electrode pads 10A are arranged, that is, a pad arranging edge (one of the longer edges) faces the first longer edge 4A of the wiring substrate 2. The first memory chip 7A is arranged in a manner that the first electrode pads 10A are positioned in a vicinity of the first pad region 6A of the wiring substrate 2.

Similarly, the second memory chip 7B is disposed in a manner that the second electrode pads 10B are positioned in a vicinity of the first pad region 6A of the wiring substrate 2. The second memory chip 7B is adhered on the first memory chip 7A via the second adhesive layer 7B to expose the first electrode pad 10A. The second memory chip 7B is displaced in a direction orthogonal to an arranging direction of the first electrode pads 10A, that is, in a direction of the shorter edge orthogonal to the longer edge along which the first electrode pads 10A are arranged. The second memory chip 7B is stacked on the first memory chip 7A in a step-like shape to expose the first electrode pads 10A. A stepped direction is a direction of the shorter edge of the first memory chip 7A, the shorter edge being orthogonal to the longer edge along which the first electrode pads 10A are arranged.

As described above, the first and second memory chips 7A, 7B are stacked in a step-like shape in a manner that the pad arranging edges (ones of longer edges) thereof face the same direction (direction of the first longer edge 4A of the wiring substrate 2), and that the longer edges (pad arranging edges) are displaced in the shorter edge direction so that the electrode pad 10A of the lower memory chip 7A is exposed. The first and second electrode pads 10A, 10B are each exposed upward based on the stacked state of the step-like structure and are positioned in the vicinity of the first pad region 6A in that state.

The electrode pads 10A, 10B of the first and second memory chips 7A, 7B are electrically connected to the connection pad 5 disposed in the first pad region 6A via metal wires. Among the electrode pads 10 of the semiconductor chips 7, with regard to the electrode pads 10 whose electric characteristics or signal characteristics are equal such as I/O terminals, the connection pad 5, the first electrode pad 10A and the second electrode pad 10B can be sequentially connected by metal wires.

As shown in FIG. 2, the electrode pad 10A of the first memory chip 7A is electrically connected to the connection pad 5 disposed in the first pad region 6A via a first metal wire 12A. The electrode pad 10B of the second memory chip 7B is electrically connected to the electrode pad 10A of the first memory chip 7A via a second metal wire 12B. The electrode pad 10B of the second memory chip 7B is electrically connected to the connection pad 5 of the wiring substrate 2 via the second metal wire 12B, the first electrode pad 10A, and the first metal wire 12A.

A part of the electrode pads 10B of the second memory chip 7B is directly connected to the connection pad 5 of the wiring substrate 2. As shown in FIG. 1, a part of the second electrode pad 10B is electrically connected to the connection pad 5 of the wiring substrate 2 via a metal wire 12C. Au wires or Cu wires are used for the metal wires 12A, 12B, 12C.

It is preferable that the first and second metal wires 12A, 12B are wire bonded by applying reverse bonding, which can decrease a loop height. The reverse bonding is a method in which a metal ball formed at a tip of a metal wire is connected to a connection portion of a lower side (first connection), and the metal wire is wired from there to a connection position of an upper side, and then, the metal wire is connected to a connection portion of the upper side (second connection).

When the reverse bonding is applied to the memory chips 7A, 7B stacked in the step-like shape, a first end (end by the first connection) of the first metal wire 12A is ball-connected to the connection pad 5, and a second end (end by the second connection) of the first metal wire 12A is connected to the first electrode pad 10A. A first end (end by the first connection) of the second metal wire 12B is ball-connected to the first electrode pad 10A, and a second end (end formed by the second connection) of the second metal wire 12B is connected to the second electrode pad 10B.

The controller chip (semiconductor chip) 9 is stacked on the memory chip group 8 constituted by the plural memory chips 7A, 7B. The controller chip 9 is stacked on the second memory chip 7B via an adhesive layer (not shown). The controller chip 9 has an L-shaped pad structure, and has electrode pads 13A arranged along a first edge (shorter edge) 9a positioned in a vicinity of the longer edge 4A of the wiring substrate 2 and electrode pads 13B arranged along a second edge (longer edge) 9b positioned in a vicinity of the shorter edge 3B of the wiring substrate 2.

The electrode pads 13A, 13B of the controller chip 9 are electrically connected to the connection pads 5 via third metal wires 14. The electrode pads 13A arranged along the shorter edge 9a of the controller chip 9 are electrically connected to the connection pads 5 disposed in the first pad region 6A via the metal wire 14. The electrode pads 13B arranged along the longer edge 9b of the controller chip 9 are electrically connected to the connection pads 5 disposed in the second pad region 6B via the metal wire 14.

A sealing resin layer (not shown) made of an epoxy resin for example is mold-formed on the surface 2a of the wiring substrate 2 on which the memory chips 7 and the controller chip 9 are mounted. The memory chips 7 and the controller element 9 together with the metal wires 12, 14 and the like are integrally sealed with the sealing resin layer. Thereby, the semiconductor device 1 used as the semiconductor memory card is constituted. Though the sealing resin layer is not illustrated in FIG. 1, the sealing resin layer is formed on the surface 2a of the wiring substrate 2 to seal the semiconductor chips 7, 9 similarly to in a common semiconductor device.

When performing wire bonding on the memory chips 7A, 7B stacked in a step-like shape by applying reverse bonding, an offset X of the second memory chip 7B (amount of displacement in the direction (shorter edge direction) orthogonal to the pad arranging direction of the second memory chip 7B) is important. In a case that the metal ball provided in the end (first end) of the second metal wire 12B is pressure-bonded to the electrode pad 10A of the first memory chip 7A, if the offset X of the second memory chip 7B is insufficient, there is a possibility that a capillary of a bonding equipment contacts an edge of the second memory chip 7B stacked on the first memory chip 7A.

In a conventional semiconductor device, a second memory chip 7B is displaced by a sufficient offset X so that a capillary does not contact an edge of the second memory chip 7B, causing hampering miniaturization of a device size. Thus, in this embodiment, there is applied a connection structure of the second metal wire 12B which can prevent a capillary from contacting the edge of the second memory chip 7B even when the offset X of the second memory chip 7B is reduced. Here, a case will be verified in which memory chips are stacked in a step-like shape so that an offset X of a second memory chip 7B becomes 280 μm.

For example, an electrode pad 10A of 90 μm in diameter is disposed so that a distance Y from its center to an edge of a memory chip 7A is 155 μm. Further, a memory chip 7B is disposed in a manner to be displaced in a shorter edge direction so that a distance Z from an edge of the electrode pad 10A to an edge of the memory chip 7B is 80 μm. In this case, the offset X of the second memory chip 7B is 280 μm. Also in a case that such an offset is applied, a structure is applied in which a first end (end to which a ball is connected) of a second metal wire 12B is connected to a metal bump formed in a first electrode pad 10A from immediately above as a connection structure not to hamper a wire bonding property to the electrode pad 10A of the lower memory chip 7A.

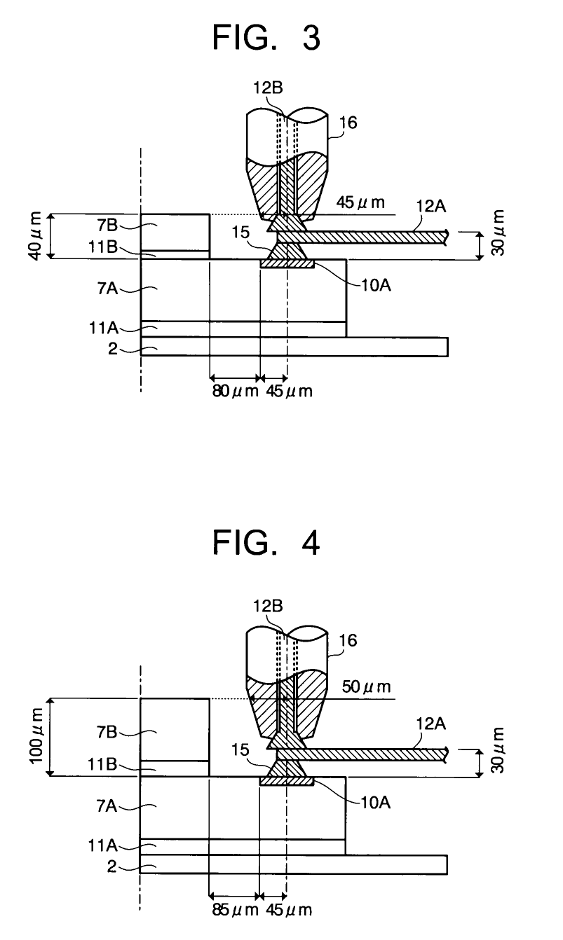

As shown in FIG. 3, a metal bump 15 is formed on the first electrode pad 10A. The metal bump (stud bump) 15 is formed by pressing a metal ball formed in a tip of a metal wire to the electrode pad 10A and then cutting the metal wire at a connection point with the metal ball for example. The metal bump 15 can be stacked in multiple layers in correspondence with a necessary height. One of the ends of the first metal wire 12A is first connected to the metal bump 15. Here, since reverse bonding is applied, the first end of the first metal wire 12A is ball-connected to the connection pad 5, while the second end is connected to the metal bump 15.

In a state that the first metal wire 12A is connected to the metal bump 15, the first electrode pad 10A becomes in a state of being elevated by a height corresponding to a height of the metal bump 15 and a diameter (diameter in consideration of a crushed amount of the wire at a connection time) of the first metal wire 12A. The first end (end having the metal ball) of the second metal wire 12B is ball-connected to the first electrode pad 10A elevated by the metal bump 15 and the first metal wire 12A. Therefore, a lowest point position (position in a state that the capillary 16 is lowered to the most extent) of the capillary 16 can be set higher by the elevated height.

When a total thickness of the second semiconductor chip 7B and a second adhesive layer 11B is 40 μm and the elevated height of the first electrode pad 10A by the metal bump 15 and the first metal wire 12A is 30 μm, a radius of the capillary 16 corresponding to a height of a corner portion of the second semiconductor chip 7B is about 45 μm, since a tip of the capillary 16 is generally sloped though depending on a shape of the capillary 16. Therefore, by disposing the memory chip 7B in a manner to be displaced in the shorter edge direction so that the distance Z from the edge of the electrode pad 10A of 90 μm in diameter to the edge of the memory chip 7B becomes 80 μm as described above, the distance from the capillary 16 at the lowest point to the edge of the memory chip 7B can be made about 80 μm.

In other words, even in a case that the distance Z from the edge of the electrode pad 10A to the edge of the memory chip 7B is equal to or less than 80 μm, since the distance from the capillary 16 at the lowest point to the edge of the upper memory chip 7B can be sufficiently kept, it is possible to stably connect the first end of the second metal wire 12B to the electrode pad 10A of the lower memory chip 7A. The above-described distance (80 μm) from the capillary 16 to the edge of the memory chip 7B is a distance in a case that a thin type semiconductor chip is applied to the second semiconductor chip 7B, and as a thickness of a semiconductor chip 7B becomes thicker, a distance from the capillary 16 to the memory chip 7B becomes shorter. Such a case will be described with reference to FIG. 4.

In a case that a chip of a general thickness (about 80 to 85 μm) is applied to a second semiconductor chip 7B, a total thickness of the second semiconductor chip 7B and a second adhesive layer 11B becomes about 100 μm. Even in such a case, with an elevated height of a first electrode pad 10A by a metal bump 15 and a first metal wire 12A being 30 μm, by disposing the memory chip 7B in a manner to be displaced in a shorter edge direction so that a distance Z from an edge of the electrode pad 10A to an edge of the memory chip 7B becomes 85 μm, a radius of a capillary 16 corresponding to a height of a corner portion of the second semiconductor chip 7B can be made about 50 μm.

In other words, even in a case that the total thickness of the second semiconductor chip 7B and the second adhesive layer 11B is about 100 μm, by disposing the memory chip 7B in a manner to be displaced in the shorter edge direction so that the distance Z from the edge of the electrode pad 10A to the edge of the memory chip 7B becomes 85 μm, the distance from the capillary 16 at the lowest point to the edge of the upper memory chip 7B can be made about 80 μm. That is, even in a case that a distance Z from an edge of an electrode pad 10A to an edge of a memory chip 7B is equal to or less than 85 μm, it is possible to stably connect a first end of a second metal wire 12B to an electrode pad 10A of a memory chip 7A.

As a result that the first end (end having a metal ball) of the second metal wire 12B is connected to the first electrode pad 10A elevated by a metal bump 15 and a first metal wire 12A from immediately above, a position of a lowest point of a capillary 16 becomes higher by an elevated height, whereby contact of the capillary 16 and the memory chip 7B can be prevented. In other words, in performing wire bonding on memory chips 7A, 7B stacked in a step-like shape, it is possible to increase connectivity of a second metal wire 12B to a electrode pad 10A of a lower memory chip 7A and reliability thereof.

As described above, in the case that the memory chip 7B is disposed in a manner to be displaced in the shorter edge direction so that the distance Z from the edge of the electrode pad 10A to the edge of the memory chip 7B becomes 80 μm, an offset X of the second memory chip 7B becomes 280 μm. In other words, even in the case that the offset X of the second memory chip is reduced to 280 μm, the second metal wire 12B can be satisfactorily connected to the electrode pad 10A of the lower memory chip 7A. Reduction of the offset X of the second memory chip 7B enables realization of a smaller semiconductor device 1. In a case of constituting a predetermined sized semiconductor device 1, it is possible to mount a larger semiconductor chip.

By applying the connection structure of the second metal wire 12B to the first memory chip 7A according to this embodiment, a connection process of the second metal wire 12B can be performed after stacking of the second memory chip 7B on the first memory chip 7A. In other words, after the first and second memory chips 7A, 7B are sequentially stacked on the wiring substrate 2, wire bonding can be performed on the respective chips 7A, 7B. Thereby, manufacturing processes of the semiconductor device are simplified and reduction and the like of a manufacturing cost can be enhanced. However, in fabricating a semiconductor device 1, performing a mounting process of the memory chips 7A, 7B and a wire bonding process separately is not excluded.

In the former manufacturing processes, a mounting process of the first memory chip 7A on the wiring substrate 2, a stacking process of the second memory chip 7B on the first memory chip 7A, a forming process of the metal bump 15 on the first electrode pad 10A, a connection process of the first metal wire 12A, and a connection process of the second metal wire 12B are sequentially performed. In the latter manufacturing processes, a mounting process of the first memory chip 7A on the wiring substrate 2, a forming process of the metal bump 15 on the first electrode pad 10A, a connection process of the first metal wire 12A, a stacking process of the second memory chip 7B on the first memory chip 7A, and a connection process of the second metal wire 12B are sequentially performed.

If the offset X (amount of displacement of the second memory chip 7B in the shorter edge direction) of the second memory chip 7B is reduced, a distance (linear distance) between the first electrode pad 10A and the second electrode pad 10B becomes shorter. Thus, sometimes a wire length (length for wiring) of the second metal wire 12B may be insufficient. If the wire length is insufficient, there is a possibility that a wiring shape is deteriorated or the second metal wire 12B contacts a corner portion of the second semiconductor chip 7B according to circumstances.

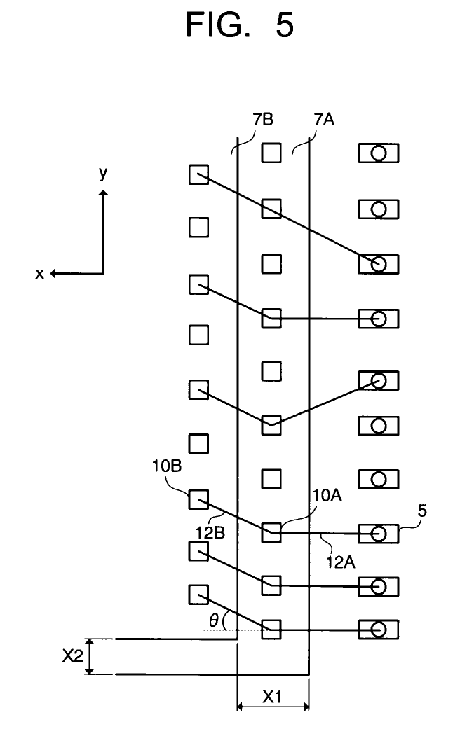

In this embodiment, as shown in FIG. 5, in addition that the second memory chip 7B is displaced in the shorter edge direction (x direction), the second memory chip 7B is displaced also in a longer edge direction (y direction) in relation to the first memory chip 7A. The second memory chip 7B is offset in the direction orthogonal to the arranging direction of the electrode pads 10 in relation to the first memory chip 7A and further offset also in the arranging direction of the electrode pads 10A.

In FIG. 5, X1 indicates an offset in the direction (shorter edge direction of the memory chip 7) orthogonal to the arranging direction of the electrode pads 10, and X2 indicates an offset in the arranging direction (longer edge direction of the memory chip 7) of the electrode pads 10. When the first offset X1 is 280 μm and further the second offset X2 is 135 μm, the second electrode pad 10B is disposed in a position displaced by the second offset X1 from the first electrode pad 10A.

As described above, as a result that the second memory chip 7B is offset in the longer edge direction (y direction) in relation to the first memory chip 7A so that the second electrode pad 10B is disposed in a position displaced by that amount from the first electrode pad 10A, the second metal wire 12B is wired in an oblique direction in relation to the direction (shorter edge direction of the memory chip 7) orthogonal to the arranging direction of the electrode pad 10. The second metal wire 12B can be wired with an angle θ in relation to the shorter edge direction of the memory chip 7. It is preferable that the angle θ is 45 degrees or less in consideration of a wiring property or the like. Thereby, a wiring length (length for wiring) of the second metal wire 12B can be kept.

For example, when the first offset X1 is 280 μm and the second offset X2 is 135 μm, a wiring angle θ of the second metal wire 12 B (degree between a wiring direction of the second metal wire 12B and the shorter edge direction of the memory chip 7) becomes about 25 degrees. Therefore, compared with a case that the second memory chip 7B is not offset (the wire length of the second metal wire 12B becomes 280 μm), a wire length of the second metal wire 12B can be extended (wire length in a case that the second metal wire 12B is wired at an angle of about 25 degrees becomes 310 μm). Thereby, a drawback (deterioration of wiring shape or the like) by insufficiency of the wire length of the second metal wire 12B can be resolved.

As a result that the offset in the shorter edge direction (x direction) and the offset in the longer edge direction (y direction) of the second semiconductor chip 7B are combinedly applied, connectivity of the second metal wire 12B to the electrode pad 10A of the lower (first) semiconductor chip 7A and the wiring shape of the second metal wire 12B itself can be preferably maintained. Therefore, in addition that the semiconductor device 1 is made smaller or the larger semiconductor chip 7 is allowed to be mounted, connection reliability by the metal wire 12B can be heightened. According to this embodiment, a small and reliable semiconductor 1 can be provided.

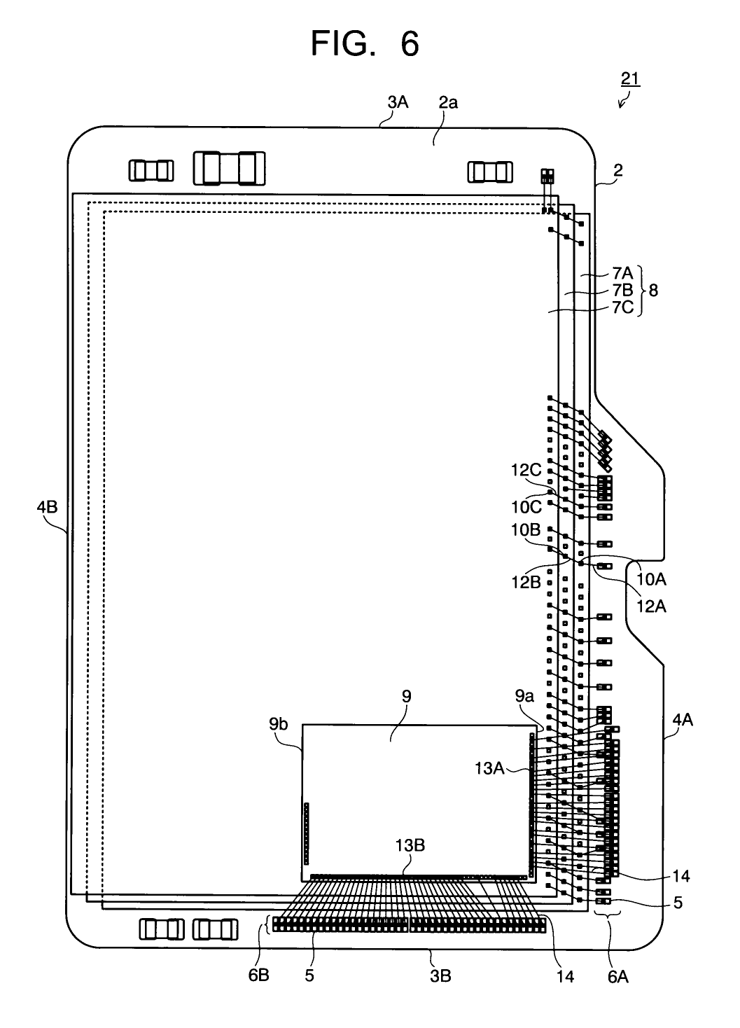

Next, a second embodiment of the present invention will be described with reference to FIG. 6 to FIG. 8. FIG. 6 is a view showing a constitution of the second embodiment in which a semiconductor device of the present invention is applied to a semiconductor memory card. A semiconductor device (semiconductor memory card) 21 shown in FIG. 6 includes a wiring substrate 2 similarly to in the first embodiment. A structure and a shape of the wiring substrate 2 are similar to those of the first embodiment. A surface 2a of the wiring substrate 2 has pad regions 6 (6A, 6B) on which chip mounting regions and connection pads 5 are provided. A plurality of memory chips (semiconductor chips) 7A, 7B, 7C are stacked on the surface 2a of the wiring substrate 2.

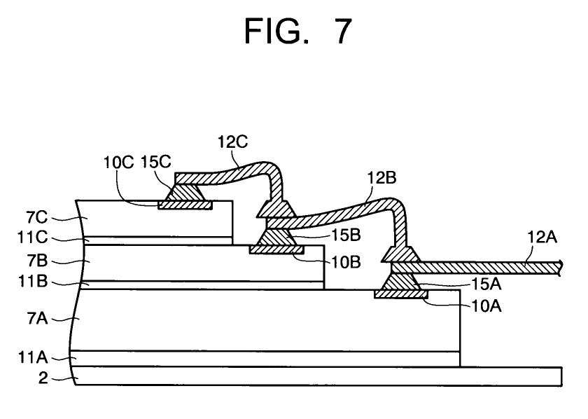

The plural memory chips 7A, 7B, 7C constitute a memory chip group 8. The first, second and third memory chips 7A, 7B, 7C have the same rectangular shapes and have electrode pads 10A, 10B, 10C respectively. The memory chips 7A, 7B, 7C have single-long-side pad structures. As shown in FIG. 7, the first memory chip 7A is adhered on the wiring substrate 2 via a first adhesive layer 11A. The second memory chip 7B is adhered on the first semiconductor chip 7A via a second adhesive layer 11B. The third memory chip 7C is adhered on the second semiconductor chip 7B via a third adhesive layer 11C.

The first to third memory chips 7A, 7B, 7C are disposed in a manner that outer edges (ones of the longer edges) along which the electrode pads 10A, 10B, 10C are arranged face a first longer edge 4A of the wiring substrate 2, similarly to in the first embodiment. The electrode pads 10A, 10B, 10C are positioned in a vicinity of the first pad region 6A of the wiring substrate 2 respectively. The second memory chip 7B is stacked on the first memory chip 7A and displaced in a direction orthogonal to an arranging direction of the first electrode pads 10A to expose the first electrode pads 10A. The third memory chip 7C is stacked on the second memory chip 7B and displaced in a direction orthogonal to an arranging direction of the second electrode pads 10B to expose the second electrode pads 10B.

As described above, the first to third memory chips 7A, 7B, 7C are stacked with the pad arranging edges (ones of the longer edges) thereof facing in the same direction (direction of the first longer edge 4A of the wiring substrate 2) and with the longer edges (pad arranging edges) being displaced in the shorter edge direction in a step-like shape so that the electrode pads 10 of the lower memory chip 7 is exposed. Offsets (X1) of the second and third memory chips 7B, 7C are similar to those of the first embodiment. Based on a stepped structure of the memory chips 7A, 7B, 7C, the electrode pads 10A, 10B, 10C are all exposed upward and positioned in the vicinity of the first pad region 6A in that state.

The first to third electrode pads 10A, 10B, 10C are electrically connected to the connection pad 5 disposed in the first pad region 6A via metal wires. The electrode pad 10A of the first memory chip 7A is connected to the connection pad 5 disposed in the first pad region 6A via the first metal wire 12A. The electrode pad 10B of the second memory chip 7B is connected to the electrode pad 10A of the first memory chip 7A via the second metal wire 12B. The electrode pad 10C of the third memory chip 7C is connected to the electrode pad 10B of the second memory chip 7B via the third metal wire 12C.

A controller chip (semiconductor chip) 9 is mounted on the memory chip group 8 constituted by the plural memory chips 7A, 7B, 7C. The controller chip 9 is stacked on the third memory chip 7C. The controller chip 9 has an L-shaped pad structure, and has electrode pads 13A arranged along a first edge (shorter edge) 9a and electrode pads 13B arranged along a second edge (longer edge) 9b. The electrode pads 13A, 13B of the controller chip 9 are electrically connected to the connection pads 5 disposed in the first pad region 6A and the second pad region 6B via the third metal wires 14, similarly to in the first embodiment.

A sealing resin layer (not shown) made of an epoxy resin for example is mold-formed on the surface 2a of the wiring substrate 2 on which the memory chips 7 and the controller chip 9 are mounted. The memory chips 7 and the controller element 9 together with the metal wires 12, 14 and the like are integrally sealed with the sealing resin layer. Thereby, the semiconductor device 21 used as the semiconductor memory card is constituted. Though the sealing resin layer is not illustrated in FIG. 6, the sealing resin layer is formed on the surface 2a of the wiring substrate 2 to seal the semiconductor chips 7, 9 similarly to in a common semiconductor device.

The first to third metal wires 12A, 12B, 12C are bonded by applying reverse bonding in which a loop height can be reduced. In the second embodiment, similarly to in the first embodiment, in order to realize miniaturization of the semiconductor device 21 (or use of larger memory chip 7), a connection structure is applied which is capable of reducing offsets (X1) of the second and third memory chips 7B, 7C while keeping bonding properties of the metal wires 12A, 12B, 12C. In other words, as a connection structure not to hamper a wire bonding property to an electrode of a lower memory chip, a structure is applied in which a first end of a metal wire is connected to a metal bump formed in an electrode pad from immediately thereabove.

As shown in FIG. 7, metal bumps 15A, 15B, 15C are formed on the electrode pads 10A, 10B, 10C similarly to in the first embodiment. A first end of the first metal wire 12A is ball-connected to the connection pad 5, while a second end is connected to the metal bump 15A formed on the first electrode pad 10A. A first end of the second metal wire 12B is ball-connected to the first metal bump 15A from immediately thereabove, and a second end is connected to the second metal bump 15B formed on the second electrode pad 10B. A first end of the third metal wire 12C is ball-connected to the second metal bump 15B from immediately thereabove, and a second end is connected to the third metal bump 15C formed in the third electrode pad 10C.

The first ends of the second and third metal wires 12B, 12C are ball-connected to the electrode pads 10A, 10B elevated by the metal bumps 15A, 15B and the metal wires 12A, 12B. Therefore, a capillary can be set higher by the elevated height from a position of a lowest point. Even if distances from the edges of the electrode pads 10A, 10B to the edges of the memory chips 7B, 7C are shorten, distances from the capillary at the lowest point to the edges of the upper memory chips 7B, 7C can be kept. Thereby, it is possible to stably connect the first ends of the metal wires 12B, 12C to the electrode pads 10A, 10B of the lower memory chip 7A, 7B.

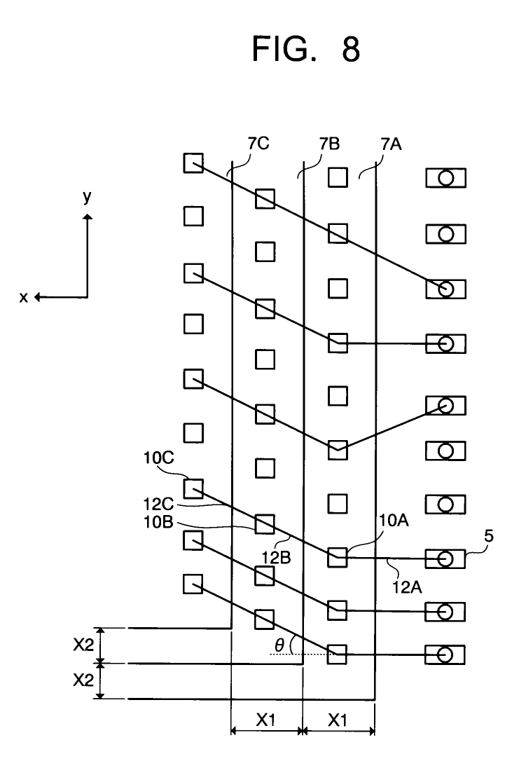

As shown in FIG. 8, the second and third memory chips 7B, 7C are displaced in a shorter edge direction (x direction) and are additionally displaced in a longer edge direction (y direction) in relation to the first memory chip 7A. The second memory chip 7B is offset in relation to the first memory chip 7A in a direction orthogonal to an arranging direction of the electrode pads 10A, and further offset also in the arranging direction of the electrode pads 10A. The third memory chip 7C is offset in relation to the second memory chip 7B in a direction orthogonal to an arranging direction of the electrode pads 10B and further offset also in the arranging direction of the electrode pads 10B.

Since the second memory chip 7B is offset in relation to the first memory chip 7A in the longer edge direction (y direction), the second electrode pad 10B is disposed in a position displaced from the first electrode pad 10A by the offset. Therefore, the second metal wire 12B is wired in an oblique direction in relation to the direction (shorter edge direction of the memory chip 7) orthogonal to the arranging direction of the electrode pad 10. Similarly, since the third electrode pad 10C is disposed in a position displaced from the second electrode pad 10B, the third metal wire 12C is wired in an oblique direction in relation to the direction (shorter edge direction of the memory chip 7) orthogonal to the arranging direction of the electrode pad 10.

The second and third metal wires 12B, 12C are wired with an angle δ in relation to the shorter edge direction of the memory chip 7. It is preferable that the angle δ is equal to or smaller than 45 degrees. Based on such a wiring shape, decrease of a linear distance between the electrode pads due to reduction of offsets (X1) of the second and third memory chips 7B, 7C and insufficiency in wiring length caused thereby can be compensated. In other words, the wiring lengths of the second and third metal wires 12B, 12C can be kept. Therefore, it is possible to keep wiring properties of the second and third metal wires 12B, 12C and connection reliability based thereon.

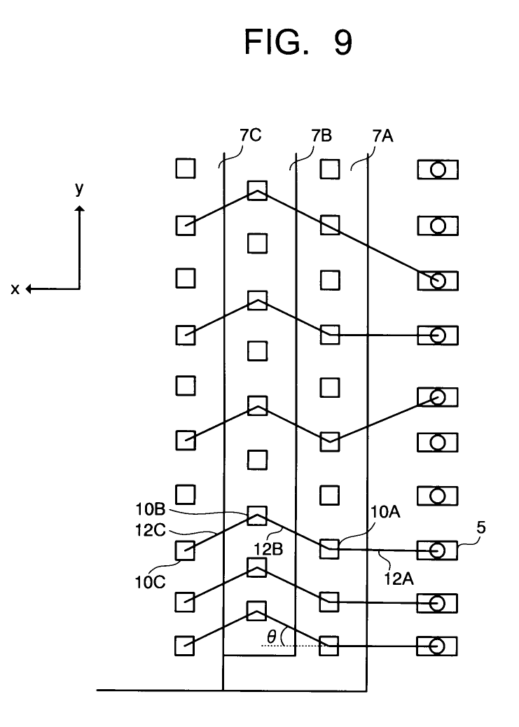

The offset of the third memory chip 7C in the y direction is not limited to in the same direction as the direction of the offset of the second memory chip 7B. As shown in FIG. 9, a third memory chip 7C can be offset in a reverse direction to a direction of an offset of a second memory chip 7B. Also in this case, a wiring length of a third metal wire 12C can be kept. The number of stacks of the memory chips 7 is not limited to two or three but can be four or more. If four or more memory chips 7 are stacked, the memory chips 7 can be disposed in a manner to be sequentially displaced similarly to in the second embodiment, or with two memory chips being made into one set, necessary numbers of sets of two memory chips can be stacked via spacers.

The semiconductor device of the present invention is not limited to the above-described embodiments and the present invention can be applied to various kinds of semiconductor devices in which a plurality of semiconductor chips are stacked and mounted on a wiring substrate in a step-like shape. The concrete structure of the semiconductor device of the present invention can be modified in various ways as long as a basic constitution of the present invention is satisfied. The embodiments can be expanded or modified in the scope of the technical spirit of the present invention and the expanded and modified embodiments are included in the technical scope of the present invention.

What is claimed is:

1. A semiconductor device, comprising:
a wiring substrate having connection pads;
a first semiconductor chip, mounted on the wiring substrate, having first electrode pads arranged along at least one outer edge and first metal bumps formed on the first electrode pads;
a second semiconductor chip, stacked on the first semiconductor chip and displaced in a direction orthogonal to an arranging direction of the first electrode pads to expose the first electrode pads, having second electrode pads arranged along at least one outer edge;
first metal wires electrically connecting the connection pads of the wiring substrate and the first electrode pads of the first semiconductor chip;
second metal wire electrically connecting the first electrode pads of the first semiconductor chip and the second electrode pads of the second semiconductor chip; and
a sealing resin layer formed on the wiring substrate to seal the first and second semiconductor chips together with the first and second metal wires,
wherein one ends of the second metal wires are connected from above the first metal bumps.

2. The semiconductor device as set forth in claim 1,
wherein the first metal wire has a first end ball-connected to the connection pad and a second end connected to the first metal bump, and the second metal wire has a first end ball-connected to the first metal bump from above and a second end connected to the second electrode pad.

3. The semiconductor device as set forth in claim 1,
wherein a distance from an edge of the first electrode pad to an edge of the second semiconductor chip is 85 μm or less.

4. The semiconductor device as set forth in claim 1,
wherein the second semiconductor chip is displaced in the arranging direction of the first electrode pads.

5. The semiconductor device as set forth in claim 4,
wherein the second metal wire is wired in an oblique direction in relation to the direction orthogonal to the arranging direction of the first electrode pads.

6. The semiconductor device as set forth in claim 5,
wherein the second metal wire is wired at an angle of 45 degrees or less in relation to the direction orthogonal to the arranging direction of the first electrode pads.

7. The semiconductor device as set forth in claim 1, further comprising:
a third semiconductor chip, stacked on the second semiconductor chip and displaced in a direction orthogonal to an arranging direction of the second electrode pads to expose the second electrode pads, having a third electrode pad arranged along at least one outer edge; and
third metal wires electrically connecting the connection pads of the wiring substrate and the third electrode pads of the third semiconductor chip,
wherein one ends of the third metal wires are connected from above second metal bumps formed on the second electrode pads of the second semiconductor chip.

8. The semiconductor device as set forth in claim 7,
wherein the first metal wire has a first end ball-connected to the connection pad and a second end connected to the first metal bump, the second metal wire has a first end ball-connected to the first metal bump from above and a second end connected to the second metal bump, and the third metal wire has a first end ball-connected to the second metal bump from above and a second end connected to the third electrode pad.

9. The semiconductor device as set forth in claim 7,
wherein a distance from an edge of the second electrode pad to an edge of the third semiconductor chip is 85 μm or less.

10. The semiconductor device as set forth in claim 7,
wherein the third semiconductor chip is displaced in the arranging direction of the second electrode pads, and
wherein the third metal wire is wired in an oblique direction in relation to the direction orthogonal to the arranging direction of the second electrode pads.

11. The semiconductor device as set forth in claim 1,
wherein the first and second semiconductor chips comprise semiconductor memory chips.

12. The semiconductor device as set forth in claim 11, further comprising:
a control chip stacked on the memory chip as the second semiconductor chip.

13. A semiconductor device, comprising:
a wiring substrate having connection pads;
a first semiconductor chip, mounted on the wiring substrate, having first electrode pads arranged along at least one outer edge;
a second semiconductor chip, stacked on the first semiconductor chip and displaced in an arranging direction of the first electrode pads and in a direction orthogonal to the arranging direction to expose the first electrode pads, having second electrode pads arranged along at least one outer edge;
first metal wires electrically connecting the connection pads of the wiring substrate and the first electrode pads of the first semiconductor chip;
second metal wires electrically connecting the first electrode pads of the first semiconductor chip and the second electrode pads of the second semiconductor chip, the second metal wires being wired in an oblique direction in relation to the direction orthogonal to the arranging direction of the first electrode pads; and
a sealing resin layer formed on the wiring substrate to seal the first and second semiconductor chips together with the first and second metal wires.

14. The semiconductor device as set forth in claim 13,
wherein the second metal wire is wired at an angle of 45 degrees or less in relation to the direction orthogonal to the arranging direction of the first electrode pads.

15. The semiconductor device as set forth in claim 13,
wherein the first metal wire has a first end ball-connected to the connection pad and a second end connected to a first metal bump formed on the first electrode pad, and the second metal wire has a first end ball-connected to the first metal bump and a second end connected to the second electrode pad.

16. The semiconductor device as set forth in claim 13,
wherein a distance from an edge of the first electrode pad to an edge of the second semiconductor chip is 85 μm or less.

17. The semiconductor device as set forth in claim 13, further comprising:
a third semiconductor chip, stacked on the second semiconductor chip and displaced in an arranging direction of the second electrode pads and in a direction orthogonal to the arranging direction to expose the second electrode pads, having third electrode pads arranged along at least one outer edge; and
third metal wires electrically connecting the connection pads of the wiring substrate and the third electrode pads of the third semiconductor chip, the third metal wires being wired in an oblique direction in relation to the direction orthogonal to the arranging direction of the second electrode pads.

18. The semiconductor device as set forth in claim 17,
wherein the first metal wire has a first end ball-connected to the connection pad and a second end connected to a first metal bump formed on the first electrode pad, the second metal wire has a first end ball-connected to the first metal bump and a second end connected to a second metal bump formed on the second electrode pad, and the third metal wire has a first end ball-connected to the second metal bump and a second end connected to the third electrode pad.

19. The semiconductor device as set forth in claim 13,
wherein the first and second semiconductor chip comprise semiconductor memory chips.

20. The semiconductor device as set forth in claim 19, further comprising:
a control chip stacked on the memory chip as the second semiconductor chip.
